(19) United States
(12) Patent Application Publication
(10) Pub. No.: US 2009/0090621 A1
(43) Pub. Date: Apr. 9, 2009

(54) Erbium Sputtering Target and Manufacturing Method

(75) Inventor: Shiro Tsukamoto, Ibaraki (JP)

Correspondence Address: HOWSON & HOWSON LLP, 501 OFFICE CENTER DRIVE, SUITE 210, FORT WASHINGTON, PA, 19034, US

(73) Assignee: NIPPON MINING & METALS CO., LTD., Tokyo (JP)

(21) Appl. No.: 12/137,856

(22) Filed: Jun. 12, 2008

(30) Foreign Application Priority Data
Jun. 21, 2007 (JP) 2007-164007

(51) Int. Cl. C23C 14/34; C22F 1/16

(52) U.S. Cl. 204/298.13; 148/559

(57) ABSTRACT

Technology for efficiently and stably providing an erbium sputtering target with low generation of particles during sputtering and capable of achieving favorable uniformity of the sputtered film, as well as a method for manufacturing such an erbium sputtering target is provided. More specifically, an erbium sputtering target is manufactured by forging and heat treatment, wherein the target purity is 3N5 or higher, and the average grain size of crystals observed in the target structure is 1 to 20 mm. The method of manufacturing an erbium sputtering target includes the steps of subjecting a vacuum-cast ingot having a purity of 3N5 or higher to constant temperature forging within a temperature range of 1100 to 1200° C., subsequently subjecting the forged target material to heat treatment at a temperature of 800 to 1200° C., adjusting the target purity to be 3N5 or higher and the average grain size of the target structure to be 1 to 20 mm, and cutting this out to obtain a target.

### BACKGROUND OF THE INVENTION

The present invention relates to an erbium sputtering target and its manufacturing method with low generation of particles during sputtering and capable of achieving favorable uniformity of the sputtered film.

Although erbium (Er) is a rare earth element, as a mineral source it exists in the earth's crust in the form of a mixed composite oxide. Although rare earth elements are given this name because they are isolated from relatively rare existing minerals, they are not that rare when viewed in relation to the entire crust.

Erbium's atomic number is 68, and it is a gray-colored metal having an atomic weight of 167.3 and comprising a hexagonal close-packed structure. Erbium has a melting point of 1530° C., a boiling point of 2860° C., and a density of 9.07 g/cm³. Erbium's surface is oxidized in the air; it gradually melts in water, and is also soluble in acid. Erbium has superior corrosion-resistance and wear-resistance properties, shows high paramagnetic property, and generates oxides (Er₂O₃) at high temperatures. With rare earth elements, it is generally said that compounds with the oxidation number 3 are stable, and erbium (Er) is also trivalent.

Recently, the refinement of LSI has progressed, and in the thinning process of 45 nm or less, introduction of High-K materials as the gate insulation film and metal gate as the gate electrode is being considered. Nevertheless, among the candidate materials of the metal gate, there is a problem in that many of them have unsuitable work functions. Here, there have been reports that indicate that the work function can be controlled by adding rare earth elements such as Er, Yb or Dy to the metal gate, and these materials are attracting attention.

As a method of adding rare earth metals, sputtering may be considered. Sputtering requires the use of a target. However, since Erbium (Er) is a fragile material at room temperature, there is a problem in that an erbium target cannot be manufactured by performing plastic working at room temperature. In addition, since erbium is a chemically active material and shows notable reaction with oxygen, moisture and carbon dioxide gas, it is also difficult to perform hot plastic working.

In light of the above, the method of manufacturing an erbium sputtering target was limited to either cutting a discoid target from an ingot prepared with the dissolution method, or directly casting molten metal into a disk shape. Nevertheless, as described above, since erbium is a fragile material at room temperature, it is difficult to manufacture a target material that is f 200 mm or greater. Moreover, in the case of a target cut from a dissolved ingot or the discoid cast target, there are problems in that there is a significant difference in the grain size at the outer periphery and center area due to the thermal gradient during the cooling process, and the uniformity of the sputtered film will become inferior.

Nevertheless, the use of erbium in electronic components was only considered recently, and conventionally not much attention was given to this metal. Therefore, there are not many documents that describe the practical application of erbium. If erbium is to be used in electronic components, the high purification of the erbium target will be required as a matter of course. However, since there is a problem in that impurities such as oxygen get mixed in during the manufacturing process of the target, there is no prior example that took measures including the manufacturing process of such a target. In addition, there are no documents that show any consideration or research regarding the particularly problematic impurities contained in the erbium target. Some reference documents are listed below, but they merely describe erbium as one of the elements in the extraction of rare earth metals.

Japanese Patent Laid-Open Publication No. S61-9533 discloses technology of manufacturing rare earth elements of Sm, Eu, Yb by mixing the oxide powders of Sm, Eu, Yb and misch metal into a briquette, and thermally reducing this in a vacuum with the misch metal as the reduction material. The misch metal is previously subject to hydrogenation treatment to obtain powdery hydrogenated misch metal, and this is mixed and molded into a briquette in order to prevent the oxidization and combustion during the pulverization process of the misch metal. In this example, although there is a scheme in the use of misch metal as the reduction material, it does not aim for higher purification, and there is a problem in that there is a limit in obtaining high purification.

Japanese Patent Laid-Open Publication No. S63-11628 proposes technology of eliminating slag from a rare earth metal by reducing halide of the rare earth metal with calcium or calcium hydride, placing a slag separating jig in molten slag, solidifying the slag, and removing the slag together with the jig. As the rare earths, lanthanum, cerium, prascodymium, and neodymium are selected. Since this technology is unable to sufficiently eliminate the slag, there is a problem in that it is difficult to achieve high purification.

Japanese Patent Laid-Open Publication No. H7-90410 proposes a manufacturing method of rare earth metals by adding a reducing agent to a fluoride raw material of rare earth metal and performing thermal reduction of heating the mixture at high temperature. As the fluoride raw material of rate earth metals, a mixed composition comprising fluorides of rare earth metals and lithium fluoride, or a mixed composition added with one or more types of barium fluoride and calcium fluoride is used. In this case, the use of a fused-salt electrolytic bath is proposed, and describes that the oxygen content will become 1000 ppm. Since this technology is based on the use of a solvent bath of fused-salt electrolysis, there are problems in that a complicated process is required and the effect of oxygen elimination is also insufficient. There is also the problem of lithium, barium, calcium and so on being included as impurities.

Japanese Patent Laid-Open Publication No. H7-90411 proposes mixing a mixed composition of fluoride and lithium fluoride of rare earth metals or a mixed composition added with one or more types of barium fluoride and calcium fluoride, and rare earth metals, and heating and melting the mixture to extract rare earths. As the rare earths, thermally reduced commercial rare earths are used, and as the mixed composition a fused-salt electrolysis solvent bath for manufacturing alloy of rare earth metals and iron group transition metals is used. Although it is thereby possible to obtain high-purity rare earth metals in which the oxygen content is 300 ppm or less, and with few impurities such as calcium, lithium and fluorine, this technology is also based on the use of a fused-salt electrolysis bath and requires a complicated process. In addition, there is a problem in that the effect of oxygen elimination is insufficient. There is also the problem of lithium, barium, calcium and so on being included as impurities.

Japanese Patent Laid-Open Publication No. H8-85833 proposes a refining method for obtaining high-purity rare earths by adding Mg or Zn to Ta-containing rare earth metals as impurities, melting the mixture in a crucible, solidifying this, eliminating the high Ta-containing portion existing at the bottom of the crucible, and performing vacuum distillation to the low Ta-containing portion. Nevertheless, there is a problem in that the added metals are included as impurities and, since the elimination of Ta is also insufficient, there is a problem in that the level of high purification is low.

As shown in the foregoing documents, the effect of refining erbium is not necessarily sufficient, and in particular only a handful of documents seek the reduction of oxygen. Among those that do, there is a problem in that the reduction of oxygen is insufficient. In addition, methods that adopt the use of fused-salt electrolysis entail a complicated process, and there is a problem in that the refining effect is insufficient. Like this, the current situation is that there is no efficient and stable manufacturing method of obtaining high-purity erbium that is a high-melting point metal, has a high vapor pressure, and in which refining is difficult in a molten state.

### SUMMARY OF THE INVENTION

An object of the present invention is to propose technology for efficiently and stably providing an erbium sputtering target with low generation of particles during sputtering and capable of achieving favorable uniformity of the sputtered film, and as well as a manufacturing method for such an erbium sputtering target.

In order to achieve the foregoing object, as a result of intense study, the present inventor discovered that using a target cut from a conventional cast as the raw material is not a suitable way to obtain an erbium sputtering target with low generation of particles during sputtering and capable of achieving favorable uniformity of the sputtered film. Additionally, the present inventor discovered that a target obtained by further subjecting the dissolved ingot to forge processing is a target superior in quality. This is the fundamental concept of the present invention, and the conditions required for this target are prioritized. The optimal conditions may be suitably selected according to the specific usage of the target.

The erbium sputtering target of the present invention is an erbium sputtering target manufactured by performing forging and heat treatment. In order to obtain a sputtered film with favorable uniformity using this erbium sputtering target, it is important that the purity of the erbium target is 3N5 or higher, and the average grain size of crystals observed in the target structure is adjusted to be 1 to 20 mm. Here, the purity of the erbium target of 3N5 or higher excludes the gas components of oxygen and carbon.

There is no conventional art that sought to adjust the structure of the erbium target from this kind of perspective. Since it is extremely difficult to adjust the average grain size to be less than 1 mm, the lower limit has been set to 1 mm. In addition, if the average grain size exceeds 20 mm, it is not possible to attain the object of obtaining favorable uniformity. Thus, the upper limit has been set to 20 mm. This forged erbium target can be achieved with the manufacturing conditions described later.

The average grain size of the erbium sputtering target is preferably further adjusted to 3 to 15 mm. Thereby, an effect is yielded in that the uniformity of the sputtered film becomes even more favorable. It is also desirable that the uniformity of the grain size of the target in the sputtered face is within ±70%. Even with a forged part, there is a distribution in the grain size at the center and periphery of the target, and the uniformity of the sputtered film can be improved by keeping this distribution within a certain range. It is even more desirable that the uniformity of the grain size of the target in the sputtered face is within ±50%. This is due to the same reason as stated above, and the quality can be improved even further.

Moreover, with the erbium sputtering target of the present invention, it is desirable that the oxygen is 100 wtppm or less and the carbon content is 150 wtppm or less in the target. This is because oxygen and carbon contained in the target as gas components cause splashes or generate particles during the sputter deposition.

With the erbium sputtering target of the present invention, it is desirable that the tungsten and the tantalum content in the target are respectively 100 wtppm or less. More preferably, the tungsten and the tantalum content in the target are respectively 20 wtppm or less.

The erbium sputtering target of the present invention is characterized in that the target diameter is f 300 mm or greater.

When manufacturing the erbium sputtering target of the present invention, the following steps are performed; namely, subjecting a vacuum-cast ingot to constant temperature forging within a temperature range of 1100 to 1200° C., subsequently subjecting the forged target material to heat treatment at a temperature of 800 to 1200° C., adjusting the average grain size of the target structure to be 1 to 20 mm, and cutting this out to obtain a target.

Moreover, the high-purity erbium ingot having a purity of 3N5 to become a raw material of the target can be manufactured by mixing erbium oxide having a purity of 3N or less as the crude material with reduced metal, and heating this to a temperature of 1500 to 2500° C. to reduce and distill erbium. According to the foregoing manufacturing method; that is, manufacturing a high-purity ingot and arbitrarily changing the forging conditions and heat treatment conditions of the ingot to obtain the intended target structure, the foregoing target can be manufactured in its entirety. The present invention covers all of the above.

The present invention yields a superior effect of being able to efficiently and stably provide an erbium sputtering target with low generation of particles during sputtering and capable of achieving favorable uniformity of the sputtered film.

### DETAILED DESCRIPTION OF THE PRESENT INVENTION

The present invention is able to use a raw material of crude erbium oxide having a purity level of 3N or lower as the erbium raw material for high purification. This raw material contains Na, K, Ca, Mg, Fe, Cr, Ni, O, C, N and so as primary impurities excluding rare earth elements. The crude erbium oxide is mixed with reducing metal and thermally reduced in a vacuum at 1500 to 2500° C. Although yttrium (Y) metal having low vapor pressure and high reducing power is effective as the reducing metal, lanthanum (La) and other reducing metals may also be used. There is no particular limitation on the type of reducing metal so as long as it has low vapor pressure and high reducing power.

Pursuant to the progress of reduction of erbium oxide, erbium is distilled and erbium with improved purity is stored in the capacitor. This distillate is melted in a crucible, and solidified into an ingot. The melting and solidification process is preferably performed in an inert atmosphere. It is thereby possible to suppress the rise in oxygen content. Although it is also possible to perform the melting and solidification process in a vacuum, since the yield tends to become inferior, it is desirable to perform the process in an inert atmosphere as described above. Nevertheless, the present invention is not denying the performance of the foregoing process in a vacuum.

High-purity erbium having a purity level of 3N5 or higher excluding gas components can thereby be manufactured. Although a unique refining method was described above, there is no particular limitation in the refining method of the present invention as long as high-purity erbium having a purity level of 3N5 or higher can be obtained. The reason why the purity level is 3N5 or greater excluding gas components is because it is difficult to eliminate gas components, and if gas components are counted, then it would not serve as a reference in the improvement of purity. Further, it is often the case that the existence of small amounts of gas components is harmless in comparison to other impurity elements.

Upon manufacturing the erbium sputtering target of the present invention, high-purity erbium having a purity level of 3N5 or greater as the raw material is subject to vacuum casting, and this cast ingot is subject to constant temperature forging in the temperature range of 1100 to 1200° C. Subsequently, the target material obtained by the constant temperature forging is subject to heat treatment at a temperature of 800 to 1200° C., and the average grain size of the forged structure is adjusted to be 1 to 20 mm. The forged part is further subject to processing such as cutting and finishing (polishing) for obtaining an erbium sputtering target in which the average grain size of crystals observed in the target structure is 1 to 20 mm.

With a conventional cast target, since the grain size differed considerably at the periphery and center of the target, there is a problem in that the uniformity of the sputtered film is significantly inferior. The forged part of the present invention, however, overcomes this conventional problem. The uniformity of the grain size of the target in the sputtered face also affects the uniformity of the sputtered film. The uniformity of the grain size of the target in the sputtered face is preferably within ±70%, and more preferably within ±50%. With this target, it is also important to adjust the level of gas components such as oxygen and carbon as well as other impurities according to the usage of the target. With that said, however, from the perspective of overcoming a significant conventional defect; namely, the uniformity of the sputtered film, what is commonly required is the adjustment of the grain size of the target. In other words, this is because the significant defect of the uniformity of the sputtered film needed to be given priority even if it meant sacrificing the level of gas components such as oxygen and carbon as well as other impurities. Accordingly, the adjustment of the grain size of the target should be considered the primary issue.

With the erbium sputtering target of the present invention, gas components; particularly oxygen and carbon, easily get mixed in and, if the oxygen content exceeds 100 wtppm and the carbon content exceeds 150 wtppm in the target, splashes will occur during sputtering due to the oxygen and carbon, and uniform deposition cannot be performed. In addition, oxides and carbides, even in trace amounts, cause the generation of particles during sputter deposition. The generation of particles will not largely affect the quality if it is a small amount, however, if the amount of particles increases, this will also deteriorate the quality of the sputtered film. More favorable deposition is enabled by the foregoing adjustment of the grain size and the restriction of gas components. Moreover, when using erbium as a metal gate film, it is obvious that oxygen and carbon should be controlled as much as possible since they will in any way affect the properties after deposition. When adjusting the oxygen content in the target, it is desirable to make it 100 wtppm or less. When adjusting the carbon content, it is desirable to make it 150 wtppm or less. This is because when the foregoing numerical values exceed in either case, no effect on the adjustment will be yielded.

Preferably, the tungsten content and the tantalum content in the erbium sputtering target are respectively 100 wtppm or less, and more preferably 20 wtppm or less. Tungsten and tantalum are generally used as crucible materials. Thus, it is often the case that they get unintentionally mixed in during the melting of rare earth materials. Nevertheless, the excessive inclusion of tungsten and tantalum will cause the generation of particles, and in certain cases change the resistance value of the film. In order to prevent this, it is desirable that the tungsten and the tantalum content are 100 wtppm or less respectively.

With the erbium sputtering target of the present invention, the diameter of the target is f 300 mm or greater. This requirement may seem like an ordinary condition. Nevertheless, a conventional erbium sputtering target could only be manufactured by casting, and the practical use and manufacturing thereof were impossible because casting causes a significant variance in the grain size and pores forming as described above, of which defects grow more prominent as the diameter of the target becomes larger. Since the present invention realizes a forged target that enables to make the diameter of the target f 300 mm or greater, this target technology did not exist conventionally. This is not an issue that should be treated lightly. In addition, there is no upper limit on the target diameter of the present invention. If there is a request for a size compatible with the sputtering device, a target of such a size can be manufactured easily. The present invention covers the foregoing aspects.

In addition, high-purity erbium can be deposited on a substrate by performing sputtering using this high-purity target. The composition of the target is reflected on the film on the substrate, and high-purity erbium film can thereby be formed. This realizes a superior effect of being able to efficiently and stably provide an erbium sputtering target with low generation of particles during sputtering and capable of achieving favorable uniformity of the sputtered film.

Although the high-purity erbium having the foregoing composition can be used as is as the metal gate film, it may also be mixed with other gate materials or formed as an alloy or a compound. This can be achieved by the simultaneous sputtering with the target of other gate materials or sputtering using a mosaic target. The present invention also covers the foregoing aspects. Although the impurity content will change depending on the impurity contained in the raw material, the respective impurities can be adjusted to be within the foregoing range by adopting the method described above.

### EXAMPLES

The present invention is now explained in detail with reference to the Examples. These Examples are merely illustrative, and the present invention shall in no way be limited thereby. In other words, various modifications and other embodiments based on the technical spirit claimed in the claims shall be included in the present invention as a matter of course.

### Examples 1 to 10

As the erbium raw material, the present invention used 2N crude erbium oxide (Er₂O₃). The impurities contained in this raw material are shown in Table 1. Subsequently, the erbium raw material was mixed with yttrium (Y) as the reducing metal, and a vacuum distillation apparatus was used to thermally reduce the mixture in a vacuum at 1600° C. Pursuant to the progress of reduction of erbium oxide, erbium was distilled and erbium with improved purity was stored in the capacitor.

Distillation and thermal reduction reaction was as follows:

Er₂O₃ (solid)+2Y (solid)→2Er (gas)+3Y₂O₃ (solid)

10 kg of erbium was extracted from the erbium distillate stored in the capacitor, and a CaO crucible was used to melt the extracted erbium in Ar atmosphere, and this was solidified into an ingot. Consequently, an ingot having a purity level of 4N was obtained.

Subsequently, this ingot was forged (upset forging of 90%) at a constant temperature of 1150° C. The ingot was thereafter subject to heat treatment at 800 to 1200° C. The ingot was cut out and ground to manufacture targets of 500 mmf having an average grain size in the range of 1 to 20 mm in 10 ranks from 1, 3, 5, . . . 17 and 20 mm. Here, although no particular differentiation was made concerning the in-plane uniformity of the grain size, they were all within ±70%. A target having an average grain size of 25 mm was also manufactured for reference. The target purity in this case was 4N, the oxygen content was 70 wtppm, the carbon content was 20 wtppm, the tungsten content was 10 wtppm, and the tantalum content was 5 wtppm. The results are shown in Table 1.

Subsequently, the target was sputtered on a Si substrate, and the generation of particles during sputtering and the uniformity of the sputtered film were checked. The results are similarly shown in Table 1. The generation of particles and the uniformity were sought as follows. Foremost, after performing pre-sputtering at approximately 10 kwh, sputter deposition was started, deposition of 5000 Å was performed for each 5 kwh, and the uniformity and particle count were measured. Particles in the size of 0.25 μm or greater were counted. The uniformity was evaluated as the standard deviation s of the film sheet resistance, and this was performed using OMNIMAP RS75 manufactured by KLA-Tencor. Incidentally, the uniformity is shown with a value representing the % of 3s in relation to the average value. The number of particles was measured using SURFSCAN 6420 manufactured by KLA-Tencor. The following measurement of the generation of particles and the uniformity was performed similarly.

Consequently, although there is no significant difference in the generation of particles during sputtering, the uniformity of the sputtered film was in the range of 10.9 to 14.5, and a favorable result was obtained. The conditions of the foregoing erbium target are the conditions that are able to most normally obtain an erbium target in the present invention excluding the difference in the average grain size. Incidentally, with Reference Example 1 having an average grain size of 25 mm, the uniformity of the sputtered film was inferior at 18.3.

As evident from the foregoing result, when the average grain size is outside the scope of the present invention, it has been discovered that there is a drawback in that the uniformity becomes deteriorated.

TABLE 1
Spread of Grain Size

| | Average Grain | Particle Generation | |
|---|---|---|---|
| Examples | Size (mm) | (Particles/cm²) | Uniformity (%, 3s) |
| Example 1 | 1 | 0.18 | 10.9 |
| Example 2 | 3 | 0.14 | 11.2 |
| Example 3 | 5 | 0.11 | 11.5 |
| Example 4 | 7 | 0.15 | 13.3 |
| Example 5 | 10 | 0.20 | 12.9 |
| Example 6 | 12 | 0.14 | 11.5 |
| Example 7 | 14 | 0.12 | 12.4 |
| Example 8 | 16 | 0.16 | 11.8 |
| Example 9 | 18 | 0.13 | 13.1 |
| Example 10 | 20 | 0.18 | 14.5 |
| Reference | 25 | 0.14 | 18.3 |
| Example 1 | | | |

Conditions:
1. Although there is no particular differentiation concerning the in-plane uniformity of the grain size, they were all within ±70%.
2. In Examples 1 to 10 and Reference Example 1, the target purity was 4N, the oxygen content was 70 wtppm, the carbon content was 20 wtppm, the tungsten content was 10 wtppm, and the tantalum content was 5 wtppm.

### Examples 11 to 20

Subsequently, targets obtained under the conditions of Example 5; namely, adjusting the average grain size to 10 mm and changing the in-plane uniformity of the target grain size within the range of ±70%, were similarly sputtered on a Si substrate, and the generation of particles during sputtering and the uniformity of the sputtered film were checked. The results are shown in Table 2. The in-plane uniformity of the target grain size of Example 5 was ±20%. As Reference Example 2, a target in which the in-plane uniformity of the target grain size is ±100% was also checked.

Consequently, the uniformity of Examples 11 to 20 in which the in-plane uniformity of the target grain size is in the range of ±70% was 10.5 to 13.8, and all showed favorable uniformity of the sputtered film. The in-plane uniformity of targets showed favorable results in the range of ±50%, particularly in the range of ±30%.

The in-plane uniformity of the target grain size of Reference Example 2 is ±100% and outside the scope of the present invention, and the uniformity of the sputtered film in this case was 20.8, and the result was slightly inferior in comparison to Examples 11 to 20.

TABLE 2
Spread of In-Plane Uniformity of Grain Size

| | In-Plane | | |
|---|---|---|---|
| | Uniformity of | Particle Generation | Uniformity |
| Examples | Grain Size | (Particles/cm²) | (%, 3s) |
| Example 5 | ±20% | 0.20 | 11.5 |
| Example 11 | ±70% | 0.21 | 13.2 |
| Example 12 | ±60% | 0.13 | 12.6 |
| Example 13 | ±50% | 0.18 | 13.8 |
| Example 14 | ±45% | 0.23 | 11.1 |
| Example 15 | ±40% | 0.14 | 12.5 |
| Example 16 | ±30% | 0.11 | 11.7 |
| Example 17 | ±10% | 0.18 | 11.5 |
| Example 18 | ±5% | 0.22 | 11.9 |
| Example 19 | ±3% | 0.15 | 10.8 |
| Example 20 | ±0% | 0.12 | 10.5 |
| Reference | ±100% | 0.20 | 20.8 |
| Example 2 | | | |

Conditions:
1. Regarding the in-plane uniformity of the grain size, Examples 11 to 20 followed conditions of Example 5, and spread only by changing the in-plane uniformity of the grain size.
2. In Example 5, the target purity was 4N, the oxygen content was 70 wtppm, the carbon content was 20 wtppm, the tungsten content was 10 wtppm, and the tantalum content was 5 wtppm.

### Examples 21 to 30

Subsequently, regarding targets obtained under the conditions of Example 5; namely, adjusting the average grain size to 10 mm and changing the in-plane uniformity of the target grain size within the range of ±20%, the generation of particles during sputtering and the uniformity of the sputtered film with the oxygen content being 100 wtppm or less and the carbon content being 150 wtppm or less were checked. The results are shown in Table 3. As Reference Example 3, a target in which the oxygen content exceeds 100 wtppm, and as Reference Example 4, a target in which the carbon content exceeds 150 wtppm were measured.

Consequently, with Examples 21 to 30 in which the oxygen content is 100 wtppm or less and the carbon content is 150 wtppm or less, the generation of particles during sputtering was low in all cases at 0.14 to 0.40 particles/cm², and the uniformity of the sputtered film was also favorable.

Reference Examples 3 and 4 respectively had an oxygen content of 110 and 150 wtppm and a carbon content of 170 and 200 wtppm, and are outside the scope of the present invention. In this case, the generation of particles during sputtering was 0.48 to 0.75 particles/cm² and increased slightly in comparison to Examples 21 to 30, and ended in an inferior result.

TABLE 3
Spread of Oxygen Content and Carbon Content

| | Oxygen | Carbon | Particle | |
|---|---|---|---|---|
| | Content | Content | Generation | Uniformity |
| Examples | (wtppm) | (wtppm) | (Particles/cm²) | (%, 3s) |
| Example 5 | 70 | 20 | 0.20 | 11.5 |
| Example 21 | 100 | 10 | 0.36 | 12.0 |
| Example 22 | 90 | 25 | 0.14 | 10.3 |
| Example 23 | 80 | 30 | 0.16 | 11.5 |
| Example 24 | 75 | 40 | 0.18 | 12.4 |
| Example 25 | 65 | 50 | 0.22 | 10.8 |
| Example 26 | 60 | 60 | 0.23 | 11.4 |
| Example 27 | 50 | 80 | 0.20 | 11.3 |
| Example 28 | 40 | 100 | 0.24 | 12.7 |
| Example 29 | 30 | 120 | 0.26 | 10.6 |
| Example 30 | 20 | 150 | 0.40 | 11.4 |
| Reference | 110 | 150 | 0.48 | 12.7 |
| Example 3 | | | | |
| Reference | 170 | 200 | 0.75 | 11.1 |
| Example 4 | | | | |

Conditions:
1. Examples 21 to 30 followed conditions of Example 5, and spread only by changing the oxygen content and carbon content.
2. In Example 5, the target purity was 4N, the oxygen content was 70 wtppm, the carbon content was 20 wtppm, the tungsten content was 10 wtppm, and the tantalum content was 5 wtppm.

### Examples 31 to 40

Subsequently, regarding targets obtained under the conditions of Example 5; namely, adjusting the average grain size to 10 mm and changing the in-plane uniformity of the target grain size within the range of ±20%, and having an oxygen content of 70 wtppm, a carbon content of 20 wtppm, a tungsten content of 10 wtppm, and a tantalum content of 5 wtppm, the generation of particles during sputtering and the uniformity of the sputtered film with the tungsten content being 100 wtppm or less and the tantalum content being 100 wtppm or less were checked. The results are shown in Table 4. As Reference Example 5, a target in which the tungsten content exceeds 100 wtppm, and as Reference Example 6, a target in which the tantalum content exceeds 100 wtppm were measured.

Consequently, with Examples 31 to 40 in which the tungsten content is 100 wtppm or less and the tantalum content is 100 wtppm or less, the generation of particles during sputtering was low in all cases at 0.14 to 0.41 particles/cm², and the uniformity of the sputtered film was also favorable.

Reference Examples 5 and 6 respectively had a tungsten content of 110 wtppm and 170 wtppm and a tantalum content of 150 wtppm and 200 wtppm, and are outside the scope of the present invention. In this case, the generation of particles during sputtering was 0.50 to 0.75 particles/cm² and increased slightly in comparison to Examples 31 to 40, and ended in an inferior result.

TABLE 4
Spread of Tungsten Content and Tantalum Content

| | | | Particle | |
|---|---|---|---|---|
| | W Content | Ta Content | Generation | Uniformity |
| Examples | (wtppm) | (wtppm) | (Particles/cm²) | (%, 3s) |
| Example 5 | 10 | 5 | 0.20 | 11.5 |
| Example 31 | 20 | 100 | 0.33 | 12.1 |
| Example 32 | 25 | 80 | 0.14 | 10.4 |
| Example 33 | 30 | 70 | 0.15 | 11.6 |
| Example 34 | 35 | 50 | 0.17 | 12.7 |
| Example 35 | 40 | 40 | 0.19 | 10.5 |
| Example 36 | 50 | 30 | 0.24 | 11.3 |
| Example 37 | 60 | 20 | 0.19 | 11.4 |
| Example 38 | 70 | 20 | 0.25 | 12.1 |
| Example 39 | 80 | 15 | 0.27 | 10.5 |
| Example 40 | 100 | 10 | 0.41 | 11.6 |
| Reference | 110 | 150 | 0.50 | 12.4 |
| Example 5 | | | | |
| Reference | 170 | 200 | 0.75 | 11.7 |
| Example 6 | | | | |

Conditions:
1. Examples 31 to 40 followed conditions of Example 5 and spread only by changing the W content and Ta content.
2. In Example 5, the target purity was 4N, the oxygen content was 70 wtppm, the carbon content was 20 wtppm, the tungsten content was 10 wtppm, and the tantalum content was 5 wtppm.

### Comparative Examples

Based on conventional casting, a f 250 mm erbium plate was manufactured, and this was cut into a target. The carbon content was 50 wtppm, the oxygen content was 300 wtppm, the tungsten content was 4000 wtppm, and the tantalum content was 5 wtppm. A target with a diameter of 300 mm f encountered a problem in that cracks were formed during the cutting process.

The average grain size of this target was 2.1 mm at the center, 1.3 mm at R/2, and 4.5 mm at the outer periphery, and the target had fine crystals. However, large pores were confirmed internally. As a result of sputtering this target, the generation of particles during sputtering was 1,357 particles, and the uniformity (3s) of the sputtered film was 20.6, and showed significantly inferior results.

### Comprehensive Evaluation of Results of Examples

With each of the foregoing Examples, the result was low generation of particles and favorable uniformity of the sputtered film. The generation of particles during sputtering and the uniformity of the sputtered film were measured using a target having a diameter of 500 mm in each of the Examples, but the same results were obtained with targets having a diameter of 300 mm and targets having a diameter exceeding 500 mm. In addition, superior targets without cracks during the manufacture process of the target, and without pores as found in cast targets were obtained.

Although targets having a comprehensive purity of 4N were used in the Examples, the same tendency was found in targets having a purity level of 3N5 to 5N.

The present invention yields a superior effect of being able to efficiently and stably provide an erbium sputtering target with low generation of particles during sputtering and capable of achieving favorable uniformity of the sputtered film, and is useful as an electronic component material.

1. An erbium sputtering target manufactured by forging and heat treatment, wherein the target purity is 3N5 or higher, and the average grain size of crystals observed in the target structure is 1 to 20 mm.

2. The erbium sputtering target according to claim 1, wherein the average grain size is 3 to 15 mm.

3. The erbium sputtering target according to claim 2, wherein the uniformity of the grain size of the target in the sputtered face is within ±70%.

4. The erbium sputtering target according to claim 2, wherein the uniformity of the grain size of the target in the sputtered face is within ±50%.

5. The erbium sputtering target according to claim 4, wherein the oxygen content is 100 wtppm or less and the carbon content is 150 wtppm or less in the target.

6. The erbium sputtering target according to claim 5, wherein the tungsten content and the tantalum content in the target are respectively 100 wtppm or less.

7. The erbium sputtering target according to claims 5, wherein the tungsten content and the tantalum content in the target are respectively 20 wtppm or less.

8. The erbium sputtering target according to anyone of claims 7, wherein the diameter of the target is f 300 mm or greater.

9. The erbium sputtering target according to claim 1, wherein the uniformity of the grain size of the target in the sputtered face is within ±70%.

10. The erbium sputtering target according to claim 1, wherein the uniformity of the grain size of the target in the sputtered face is within ±50%.

11. The erbium sputtering target according to claim 1, wherein the oxygen content is 100 wtppm or less and the carbon content is 150 wtppm or less in the target.

12. The erbium sputtering target according to claim 1, wherein the tungsten content and the tantalum content in the target are respectively 100 wtppm or less.

13. The erbium sputtering target according to anyone of claims 1, wherein the tungsten content and the tantalum content in the target are respectively 20 wtppm or less.

14. The erbium sputtering target according to anyone of claims 1, wherein the diameter of the target is f 300 mm or greater.

15. A method of manufacturing an erbium sputtering target, comprising the steps of:
subjecting a vacuum-cast ingot having a purity of 3N5 or higher to constant temperature forging within a temperature range of 1100 to 1200° C.;
subsequently subjecting the forged target material to heat treatment at a temperature of 800 to 1200° C.;
adjusting the target purity to be 3N5 or higher and the average grain size of the target structure to be 1 to 20 mm; and
cutting this out to obtain a target.

16. The method of manufacturing an erbium sputtering target according to claim 15, wherein, upon reducing and distilling erbium by mixing and heating erbium oxide as a raw material having a purity of 3N or lower with reduced metal, this is heated to a temperature of 1500 to 2500° C. to manufacture high-purity erbium having a purity of 3N5, and an ingot obtained by vacuum casting the high-purity erbium is used for manufacturing the erbium sputtering target.
